(19) United States
(12) Patent Application Publication
(10) Pub. No.: US 2009/0047426 A1
(43) Pub. Date: Feb. 19, 2009

(54) DEPOSITION APPARATUS

(75) Inventors: Hyung Sang PARK, Seoul-si (KR); Jong Su Kim, Cheonan-si (KR)

Correspondence Address: KNOBBE MARTENS OLSON & BEAR LLP, 2040 MAIN STREET, FOURTEENTH FLOOR, IRVINE, CA, 92614, US

(73) Assignee: ASM Genitech Korea Ltd., Cheonan-si (KR)

(21) Appl. No.: 12/176,270

(22) Filed: Jul. 18, 2008

(30) Foreign Application Priority Data
Aug. 17, 2007 (KR) 10-2007-0082629

(51) Int. Cl. C23C 16/00

(52) U.S. Cl. 427/248.1; 118/715

(57) ABSTRACT

A deposition apparatus for depositing a thin film on a substrate according to an embodiment of the present invention includes a substrate support, a reaction chamber wall formed above the substrate support and defining a reaction chamber, a gas inflow tube having a plurality of gas inlets connected to respective process gas sources and communicating with the reaction chamber, a volume adjusting horn for supplying a process gas to the reaction chamber, which defines a reaction space together with the substrate support, a micro-feeding tube assembly disposed between the gas inflow tube and the volume adjusting horn and having a plurality of fine tubules, and a helical flow inducing plate disposed between the micro-feeding tube assembly and the volume adjusting horn, and the process gas passing through the volume adjusting horn is directly supplied to the substrate without passing any other device. The process gases may be supplied to the substrate quickly and uniformly without any downstream gas dispersion device, such as a showerhead.

### CROSS-REFERENCE TO RELATED APPLICATIONS

This application claims priority under 35 U.S.C. §119(a) to and the benefit of Korean Patent Application No. 10-2007-0082629 filed in the Korean Intellectual Property Office on Aug. 17, 2007, the entire contents of which are incorporated herein by reference.

### BACKGROUND OF THE INVENTION

1. Field of the Invention

The present invention relates to a deposition apparatus. More particularly, the present invention relates to a chemical vapor deposition (CVD) apparatus or an atomic layer deposition (ALD) apparatus that is capable of independently streaming a plurality of process gases to a reactor, mixing the independently streamed process gases in the reactor, and supplying the gases uniformly to a substrate loaded into the reactor.

2. Description of the Related Art

In fabrication of a semiconductor device, a chemical vapor deposition (CVD) method or an atomic layer deposition (ALD) method is used for depositing a thin film on a substrate.

In the chemical vapor deposition method (CVD), reactive process gases are simultaneously supplied and vapor phase process gases react to deposit a thin film on a substrate.

In the ALD method, the process gases are separately supplied, alternately and sequentially, to the substrate, at least one process gas is chemisorbed in a self-limiting manner on a substrate without thermal decomposition, and a thin film is formed by units of an atomic layer by surface chemical reaction with subsequent process gases.

It is important that process gases are quickly and uniformly supplied to a substrate on which a thin film is deposited, in both the CVD method and the ALD method.

In general, a gas dispersion device like a showerhead is used for supplying source gases uniformly on the substrate in the known CVD apparatus and ALD apparatus. The showerhead is disposed opposite the substrate, and has a plurality of fine tubules such that the process gases are passed through the fine tubules to be uniformly supplied to the substrate.

The showerhead (or similar dispersion devices) spread the gas flow from a rather narrow inlet tube across the width of the substrate by using a plurality of small openings to generate back pressure in the showerhead plenum, thus encouraging a more uniform spread of reactant gases. By the same token, such back pressure interrupts the flowing of the process gas as well as slowing the conversion or replacement of the process gases, especially in the ALD apparatus wherein the process gases are to be supplied and purged repeatedly and quickly.

The above information disclosed in this Background section is only for enhancement of understanding of the background of the invention and therefore it may contain information is not prior art.

### SUMMARY OF THE INVENTION

The illustrated embodiments provide deposition apparatuses having advantages of inflowing a plurality of process gases independently, mixing the process gases in the reactor appropriately, and supplying the process gases to the substrate quickly and uniformly without any gas dispersion device, like a showerhead, which would interrupt uniform gas flows in CVD or ALD apparatus.

A deposition apparatus for depositing a thin film on a substrate according to an embodiment of the present invention includes a substrate support; a reaction chamber wall which contacts the substrate support and therefore defines a reaction chamber; a gas inflow tube having a plurality of gas inlets connected to a plurality of process gas sources and communicating with the reaction chamber; a volume adjusting horn for supplying a process gas to the reaction chamber, which defines a reaction space together with the substrate support; a micro-feeding tube assembly disposed between the gas inflow tube and the volume adjusting horn and having a plurality of fine tubules; and a helical flow inducing plate disposed between the micro-feeding tube assembly and the volume adjusting horn. The process gas passing through the volume adjusting tube is directly supplied to the substrate without an intervening gas dispersion device.

A plurality of fine holes may be formed at an upper portion of the helical flow inducing plate. A plurality of grooves, which direct gas flow direction passing through the gas inflow tube and one mixing region at the center of the grooves, may be formed at a lower portion of the helical flow inducing plate.

The helical flow inducing plate may include a plurality of grooves extending in a plane substantially parallel to the substrate support, and the grooves may be configured to direct gases in the volume adjusting horn in a direction substantially perpendicular to the substrate support.

The helical flow inducing grooves may have a shape that is curved clockwise, the mixing region may be disc-shaped, and the inducing grooves may be connected to the mixing region so as to contact a circumference of the mixing region.

The helical flow inducing grooves may have a shape that is curved counterclockwise, the mixing region may be disc-shaped, and the inducing grooves may be connected to the mixing region so as to contact a circumference of the mixing region.

The deposition apparatus may further include a gas outlet for exhausting gas from the reaction chamber and an RF connection port connected to the volume adjusting horn to supply RF power. Another part of the apparatus (e.g., walls or substrate support) is connected to an opposite terminal of the RF power supply, or to ground, such that an in situ plasma can be ignited within the reaction chamber.

The gas outlet may be disposed at the center of the deposition apparatus, and the process gases supplied to the substrate may be subject to collinear exhalation power by the gas outlet.

The upper portion of the volume adjusting horn may have a diameter surrounding the plurality of fine tubules of the helical flow inducing plate, and the inner diameter of the volume adjusting horn may widen to the lower end, closer to the substrate support.

The upper portion of the volume adjusting horn may be connected to the helical flow inducing plate, and the inner diameter of the volume adjusting horn may widen to the lower end.

The helical flow inducing plate may be electrically and mechanically connected to the volume adjusting horn.

The micro-feeding tube assembly may include an electrically conductive micro-feeding tube sub-assembly connected to the gas inflow tube and an insulating micro-feeding tube sub-assembly connected to the helical flow inducing plate, each of the sub-assemblies having the fine tubules.

Each of the fine tubules of the helical flow inducing plate may be aligned with one of the fine tubules of the insulating micro-feeding tube sub-assembly to form a plurality of single conduits.

The gas inflow tube and the micro-feeding tube assembly may be configured to introduce gases substantially perpendicular to the helical flow inducing plate.

Inner diameters of the fine tubules of the electrically conductive micro-feeding tube sub-assembly and the insulating micro-feeding tube sub-assembly may be in a range of 0.1 mm to 1.2 mm

Each of the fine tubules of the electrically conductive micro-feeding tube sub-assembly may be aligned with one of the fine tubules of the insulating micro-feeding tube sub-assembly to form a plurality of single conduits.

In another embodiment, an inlet structure for a vapor deposition tool is provided. The structure includes a plurality of gas inlets connected to separate vapor sources. A plurality of grooves communicate with and are downstream of the gas inlets for inducing a helical flow. A mixing region communicates with and is downstream of the grooves for receiving and mixing vapor from the grooves. A volume adjusting horn communicates with and is downstream of the mixer region. The volume adjusting horn includes a widening downstream portion facing a major surface of a substrate support with no restriction between the widening downstream portion and the substrate support.

In another embodiment, a method of feeding a plurality of process gases is provided. The method includes feeding a plurality of process gases through separate inlets. A plurality of process gases merge and mix in a helical flow. The mixed process gases pass through an expanding path in a net perpendicular direction to the surface of the substrate without restriction from the expanding path to the surface.

### BRIEF DESCRIPTION OF THE DRAWINGS

FIG. 1 is a schematic cross-sectional view of a deposition apparatus according to an embodiment of the present invention.

FIG. 2 is an enlarged partial cross-sectional view of the process gas inflow unit of the deposition apparatus according to an embodiment of the present invention.

FIG. 3 is a schematic perspective view showing upper and lower portions of a helical flow inducing plate of the deposition apparatus according to an embodiment of the present invention.

FIG. 4 is a schematic isometric view showing a gas flow in the process gas inflow unit of the deposition apparatus according to an embodiment of the present invention.

### DETAILED DESCRIPTION OF THE PREFERRED EMBODIMENT

Hereinafter, exemplary embodiments of the present invention will be described in detail with reference to the attached drawings such that the present invention can be easily put into practice by those skilled in the art. The present invention can be embodied in various forms, but is not limited to the embodiments described herein. In the drawings, thicknesses are enlarged for the purpose of clearly illustrating layers and areas. In addition, like elements are denoted by like reference numerals throughout the specification.

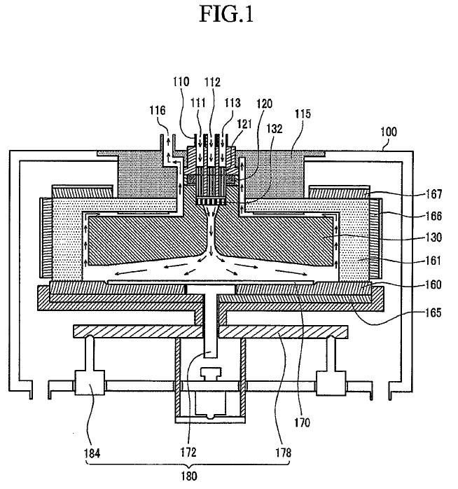

A deposition apparatus according to an embodiment of the present invention will be described in detail with reference to FIG. 1. FIG. 1 is a schematic cross-sectional view of a deposition apparatus according to an embodiment of the present invention.

Referring to FIG. 1, the deposition apparatus according to an embodiment of the present invention deposition apparatus includes an outer apparatus wall 100, a gas manifold 115, a gas inflow tube 110, a gas outlet 116, an electrically conductive micro-feeding tube sub-assembly 121, an insulating micro-feeding tube sub-assembly 120, a helical flow inducing plate 132, a reaction chamber wall 161, heaters 166 and 167, a volume adjusting horn 130, a substrate support 160 in the form of pedestal 160, a pedestal driver 180.

Now, these components will be described in detail.

A substrate 170 that is subject to deposition is mounted on the substrate support 160, and a heating plate 165 is disposed under the substrate support 160 to increase the temperature of the substrate to a desired process temperature.

The pedestal driver 180 for moving the substrate support 160 up and down includes a central supporting pin 172 for supporting the substrate support 160 and a moving plate 178 linked to pneumatic cylinders 184, the other ends of which are fixed at a lower portion of the outer apparatus wall 100 of the deposition apparatus.

Before or after the deposition process, the substrate support 160, which is connected to the pneumatic cylinders 184, is moved down such that the reaction chamber wall 161 and the substrate support 160 are detached, so that the reaction chamber opens. While the reaction chamber opens, the central supporting pin 172 may be lifted up or moved down, relative to the substrate support, so that the substrate 170 can be detached from the substrate support 160 or mounted on the substrate support 160, respectively. The substrate 170 can be loaded or unloaded while the central supporting pin 172 is lifted up relative to the substrate support 160.

After placing a new substrate for deposition, the central supporting pin 172 is dropped down relative to the substrate support, and the substrate 170 is mounted on the substrate support 160. Then, or in the same motion, the substrate support 160 is lifted up by the pneumatic cylinders 184 close to the reaction chamber wall 161, so that the reaction chamber is closed and reaction space is defined by contact between upper portion of the substrate support 160 and lower portion or a base plate (not shown) of the reaction chamber wall 161.

In order to maintain a suitable inner temperature of the reaction chamber, the separate heaters 166 and 167 are provided on outer surfaces of the reaction chamber wall 161. In order to prevent the loss of heat that is generated by the heaters 166 and 167 to the outer apparatus wall 100, the reaction chamber wall 161 has a minimal heat conduction path to the outer wall 100, i.e., the chamber wall 161 is mechanically fixed to the outer apparatus wall 100 through the flanged cylinder-type gas manifold 115. Due to such a structure, even though the inner temperature of the reaction chamber is, for example, about 300° C., the temperature of the outer apparatus wall 100 can be maintained at about 65° C., or below. Additional heaters (not shown) may be attached to the gas manifold 115 or inserted into the gas manifold 115 in case heat loss of the deposition apparatus is too high or greater control over temperature is needed.

The gas inflow tube 110, including a plurality of gas inlets 111, 112, and 113 for supplying a plurality of process gases, is positioned in the central portion of the gas manifold 115. The electrically conductive micro-feeding tube sub-assembly 121 having a plurality of fine tubules is disposed under and downstream of the gas inflow tube 110. The insulating micro-feeding tube sub-assembly 120 has a plurality of fine tubules that in the illustrated embodiment have the same geometries as those of the electrically conductive micro-feeding tube sub-assembly 121. It is disposed under and downstream of the electrically conductive micro-feeding tube sub-assembly 121. The fine tubules of the electrically conductive micro-feeding tube sub-assembly 121 and the insulating micro-feeding tube sub-assembly 120 are shown as aligned, and each of the fine tubules 120, 121 may be of a size (e.g., diameter) in a range from 0.1 mm to 1.2 mm. The helical flow inducing plate 132 is disposed under and apart from the insulating micro-feeding tube sub-assembly 120. The helical flow inducing plate 132 includes a plurality of fine holes that can have the same geometries as those of the electrically conductive micro-feeding tube sub-assembly 121 and the insulating micro-feeding tube sub-assembly 120, and that are aligned and connected to those of the electrically conductive micro-feeding tube sub-assembly 121 and the insulating micro-feeding tube sub-assembly 120.

The helical flow inducing plate 132 is for the illustrated embodiment made of a conductive material and is electrically and mechanically connected to the volume adjusting horn 130. The volume adjusting horn 130 has an inner shape that broadens toward the substrate 170 or substrate support 160. The volume adjusting horn 130 has a trumpet-shape or a conical shape, the upper end of which matches the diameter of the helical flow inducing plate 132, and downstream of which the internal passage first narrows to form a restriction. A gas receiving region is thus formed between the upper end of the internal passage and the intermediate restriction. Downstream of the restriction, the internal passage of the volume adjusting horn 130 widens toward the lower or downstream end, which is shown as larger than the diameter of the substrate 170 that is opposite thereto.

The gas outlet 116 of the illustrated embodiment is disposed next to the gas inflow tube 110 and in the central portion of the deposition apparatus. The gas outlet 116 exhausts the process gases inflowing to the reactor collinearly. In FIG. 1, the arrows denote the flow directions of the process gases.

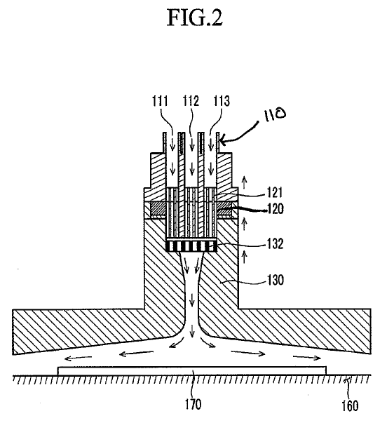

Now, supplying of process gases to the substrate 170 of the deposition apparatus according to the embodiment of the present invention will be described with reference to FIG. 2 to FIG. 4.

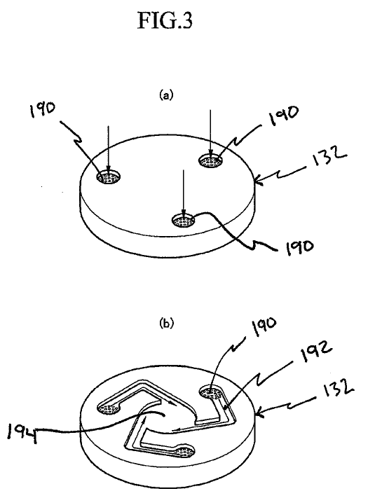

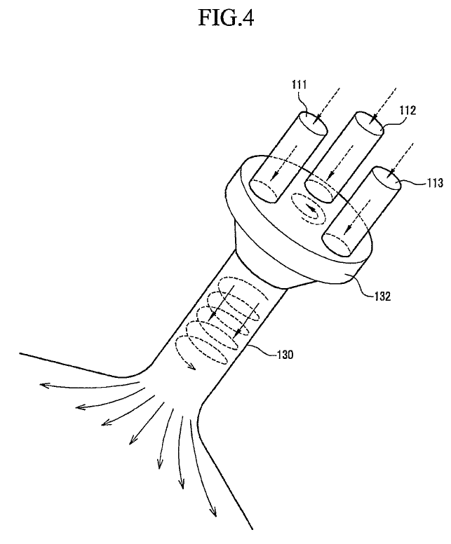

FIG. 2 is an enlarged partial cross-sectional view of the process gas inflow unit of the deposition apparatus according to an embodiment of the present invention, FIG. 3 is a schematic perspective view showing upper and lower portions of a helical flow inducing plate of the deposition apparatus according to an embodiment of the present invention, and FIG. 4 is a schematic isometric view showing a gas flow pattern in the process gas inflow unit of the deposition apparatus according to an embodiment of the present invention.

In FIG. 2, the arrows denote the flow direction of the process gases. The process gases are supplied through the gas inlets 111, 112, and 113 of the gas inflow tube 110, and then pass in sequence through the electrically conductive micro-feeding tube sub-assembly 121, the insulating micro-feeding tube sub-assembly 120, and the helical flow inducing plate 132. Process gases pass the helical flow inducing plate 132 and are then dispersed inside the volume adjusting horn 130 such that the process gases are radially spread or dispersed and uniformly supplied to the substrate 170.

The gas inlets 111, 112, and 113 are separated from each other so as to separately supply each of a plurality of process gases. The electrically conductive micro-feeding tube sub-assembly 121 and the insulating micro-feeding tube sub-assembly 120 have a plurality of the fine tubules that are disposed in parallel to each other. Each of the fine tubules of the electrically conductive micro-feeding tube sub-assembly 121 are connected to and are aligned with one of fine tubules of the insulating micro-feeding tube sub-assembly 120 to form a plurality of single, continuous fine conduits. A plurality of fine holes that have the same number, positions, and diameters as the fine tubules of the electrically conductive micro-feeding tube sub-assembly 121 and insulating micro-feeding tube sub-assembly 120 are formed in an upper portion of the helical flow inducing plate 132. These holes are to be aligned to the fine tubules of the micro-feeding tube assemblies 121 and 120.

The plurality of fine tubules in the micro-feeding tube sub-assemblies 121 and 120 suppress generation of plasma within the fine conduits because electrons in such a narrow space cannot be accelerated enough to ionize other molecules or atoms, and thus do not generate plasma. The insulating micro-feeding tube sub-assembly 120 maintains electrical insulation between the electrically conductive micro-feeding tube sub-assembly 121 and the helical flow inducing plate 132 while allowing the process gases to pass through the fine tubules.

The helical flow inducing plate 132 is electrically connected to the volume adjusting horn 130 so as to have an electrical potential equal to that of the volume adjusting horn 130. Accordingly, when RF power is supplied to the volume adjusting horn 130, there is no potential difference between the volume adjusting horn 130 and the helical flow inducing plate 132. Therefore, plasma is not generated in a space between the volume adjusting horn 130 and the helical flow inducing plate 132. The gap between lower ends of the fine tubules of the insulating micro-feeding tube sub-assembly 120 and the helical flow inducing plate 132 is designed to be narrow (for example, 2 mm or less) enough to prevent or suppress plasma generation.

On the other hand, if the process gases are mixed outside (upstream of) the volume adjusting horn 130, whether ALD or CVD, conductive materials or contaminants may be generated due to chemical reactions between the process gases. Therefore, it is desirable to keep the process gases from mixing outside the volume adjusting horn 130.

In the deposition apparatus according to the illustrated embodiment, a plurality of the fine tubules are provided to the electrically conductive micro-feeding tube sub-assembly 121 and the insulating micro-feeding tube sub-assembly 120, and a plurality of the fine holes are provided in the upper portion of the helical flow inducing plate 132. Therefore, the flow rate of the process gases in the fine tubules 121 and 120, and the holes 190 in the plate 132, all of which have relatively small diameters, is higher than the flow rate of the process gases in the gas inlets 111, 112, and 113, which have relatively larger diameters. This higher flow rate prevents back-diffusion of the process gases into the gas inlets 111, 112, and 113, and thus prevents mixing of those gases outside (upstream of) the volume adjusting horn 130. Also, there is no mixing of reactive gases passing through the inside of the fine conduits because the fine tubules are separated for each process gas flow.

In the deposition apparatus according to the illustrated embodiment, the helical flow inducing plate 132 has a function of effectively mixing the process gases after they pass through the separate fine conduits by inducing helical flows having a clockwise or counterclockwise direction. Note that, in operation by ALD method, only one reactant is typically flowed at a time, but the others of the inlets 111, 112, and 113 typically include a flowing inert gas while a reactant flows through one of the inlets 111, 112, and 113. Thus, typically inert and reactant flows are mixed well in the upper part of the volume adjusting horn 130 , rather than mutually reactive reactants. The inert gas may also serve as a reactant, but only upon activation by plasma below the gas inflow unit.

In FIG. 3, (a) is a schematic view of the top view of the helical flow inducing plate 132, and (b) is the bottom view of the helical flow inducing plate 132. As shown in FIG. 3, a plurality of fine holes 190 are formed in the upper portion of the helical flow inducing plate 132 for connecting to the electrically conductive micro-feeding tube sub-assembly 121 and the insulating micro-feeding tube sub-assembly 120. As shown, the holes 190 are bundled in groups (three shown) to match the number of gas inlets 111, 112, 113. Grooves 192 are formed in the lower face of the helical flow inducing plate 132, which grooves 192 are skewed clockwisely or counter-clockwisely. The grooves 192 direct gas flows to a central disc-shaped mixing region 194 or recess, which opens to the upper part of the volume adjusting horn 130 (see FIG. 2). Process gases passing through the grooves 192 form a helical flow and mix well with each other at the mixing region 194. The grooves 192 shown in (b) of FIG. 3 are turned about 90° within a horizontal plane parallel to the substrate, however, they may have a shape of a straight line, an arc, or other shapes.

The process gases passing through the electrically conductive micro-feeding tube sub-assembly 121, the insulating micro-feeding tube sub-assembly 120, and the fine holes in the upper portion of the helical flow inducing plate 132 are mixed, skewed and accelerated downward at a high flow rate when passing through the narrow helical flow inducing grooves into the mixing region 194.

In FIG. 4, the arrows indicate the flow direction of the process gases. As shown in FIG. 4, the process gases flowing into the gas inlets 111, 112, and 113, substantially perpendicular to the substrate surface, pass through the electrically conductive micro-feeding tube sub-assembly, the insulating micro-feeding tube sub-assembly, and the fine holes 190 in the upper portion of the helical flow inducing plate 132. The fine tubules of the sub-assemblies 120, 121 (FIG. 2) are omitted from FIG. 4 for simplicity. The flows of process gases are turned roughly parallel to the substrate, rotate clockwisely or counterclockwisely when passing through the narrow inducing grooves 192 in the lower portion of the helical flow inducing plate 132, and are again provided with a flow component vector substantially perpendicular to the substrate when passing from the central disc-shaped mixing region 194 at the lower side of the plate 132 into the volume adjusting horn 130. These helical flows mix well the gases flowing from the various inlets 111, 112, and 113 inside the narrow upper portion of volume adjusting horn 130. These helical flows are maintained in the volume adjusting horn 130, and then the process gases are uniformly dispersed in a radial direction to the substrate 170 by widening of the volume adjusting horn 130.

The inner portion of the volume adjusting horn 130 has a shape of a funnel so as to induce a laminar flow and smooth dispersion of the mixed process gases and suppress turbulence. The horn shape also minimizes the inner surface area of the volume adjusting horn 130, relative to use of an intervening gas dispersion device like a showerhead plate. Laminar flow and a minimal surface area facilitate rapid switching of process gases in the volume adjusting horn 130. Rapid gas switching due to a minimal surface area allows more ALD cycles per unit time, higher film growth rate and reduced risk of gas phase reaction between process gases by residual process gases.

Together with the helical flow inducing plate 132, the volume adjusting horn 130 produces a more uniformly distributed (across the substrate surface) and well mixed process gas during each of the relatively short ALD pulses. Accordingly, an ALD apparatus using the deposition apparatus according to an embodiment of the present invention deposition apparatus enables deposition of a thin film at a high deposition rate.

For CVD processes, of course, the inlet structure mixes reactants well and spreads the mixture across the substrate without back-pressure generating dispersion devices, thus reducing the incidence of premature reaction.

Advantageously, the helical flow inducing plate 132 generate a swirling action that distributes the process gas or gas mixture symmetrically about the gas flow axis, and directly disperses the gas mixture to the substrate 170 without any other gas dispersion structure (such as a gas dispersion perforated grid or showerhead faceplate) even though each process gas may be asymmetrically introduced through one of the gas inlets 111, 112, and 113. Additionally, if during one pulse a reactant is introduced through one of the gas inlets 111, 112, and 113 and inert gas is introduced through another of the gas inlets 111, 112, and 113, the swirling action mixes these process (reactant+inert) gases to improve uniformity of the exposure of the substrate to the reactant within the mixture. Accordingly, the helical flow inducing plate 132, downstream of the separate gas inlets 111, 112, and 113, provides improved distribution uniformity regardless of the presence, absence or geometry of a gas dispersion structure between the helical flow inducing plate 132 and the face of the substrate 170. Accordingly, in the illustrated embodiment, the process gases passing the volume adjusting horn 130 are directly and uniformly supplied to the whole surface of the substrate 170 without any other intervening structure such as a gas dispersion perforated grid or faceplate. The process gases are more quickly supplied to the whole surface of the substrate 170 in comparison to the same structure with an additional gas dispersion structure, because no sacrifice in mixing uniformity has been found despite the lack of backpressure. After the process gases are supplied to the substrate 170, any unreacted process gas or by-product is exhausted through the gas outlet 116. As described above, as the gas outlet 116 is disposed in the center position of the upper portion of the deposition apparatus, the process gases may be symmetrically exhausted uniformly and thus are drawn with a radial shape across the substrate 170. Accordingly, the process gases supplied to the substrate 170 are uniformly subjected to suction power from the gas outlet 116 disposed in the center position of the upper position of the deposition apparatus such that the process gases supplied to the substrate 170 are uniformly and symmetrically pulled across the substrate 170 by the radially symmetrical, central exhaust.

When the deposition apparatus according to an embodiment of the present invention is used for an ALD apparatus, the process gases may be sufficiently mixed and then supplied to the surface of the substrate 170 by the helical flow inducing plate 132 and the volume adjusting horn 130 of the ALD apparatus, even with very short reactant pulses.

Even though the process gases passing through the gas inlets 111, 112, and 113, the electrically conductive micro-feeding tube sub-assembly 121, the insulating micro-feeding tube sub-assembly 120, and the upper portion of the helical flow inducing plate 132 are asymmetrical, the process gases passing the lower portion of the helical flow inducing plate 132 are dispersed radially and symmetrically with respect to the surface of the substrate 170. In addition, one process gas incoming through one gas inflow of the gas inlets 111, 112, and 113 is well mixed with other process gases incoming through the other gas inlets of the gas inlets 111, 112, and 113 and then the mixed process gases are uniformly supplied to the substrate 170. The helical flow inducing plate 132 causes the process gases flowing in a net perpendicular direction to the surface of the substrate to be symmetrical and uniform without any other gas dispersion structure such as a gas dispersion perforated grid or faceplate. As the gas outlet 116 is disposed in the center of the upper position of the deposition apparatus to exhaust the process gases symmetrically, radially and uniformly from the substrate 170, the process gases supplied to the substrate 170 are uniformly subjected to suction power from the gas outlet 116 such that the process gases supplied to the substrate 170 are uniformly dispersed and exhausted from the substrate 170.

Accordingly, the deposition apparatus according to an embodiment of the present invention may cause the process gases to be quickly and uniformly supplied to the substrate without any other gas dispersion device, avoiding the slow down and premature reaction that backpressure can cause. No restriction is presented between the widening section of the volume adjusting horn 130 and the substrate on the substrate support 160.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus for depositing a thin film on a substrate, comprising:
a substrate support;
a reaction chamber wall formed above the substrate support and defining a reaction chamber;
a gas inflow tube having a plurality of gas inlets connected to a plurality of process gas sources and communicating with the reaction chamber;
a volume adjusting horn for supplying a process gas to the reaction chamber, which defines a reaction space together with the substrate support;
a micro-feeding tube assembly disposed between the gas inflow tube and the volume adjusting horn and having a plurality of fine tubules; and
a helical flow inducing plate disposed between the micro-feeding tube assembly and the volume adjusting horn,
wherein the process gas passing through the volume adjusting horn is directly supplied to the substrate without an intervening gas dispersion device.

2. The deposition apparatus of claim 1, wherein the helical flow inducing plate includes an upper portion where a plurality of fine holes are formed, and a lower portion where a plurality of inducing grooves for inducing a direction of the gas inflowing through the fine holes and one mixing region at the center of the grooves are formed.

3. The deposition apparatus of claim 2, wherein the helical flow inducing plate comprises a plurality of inducing grooves extending in a plane substantially parallel to the substrate support, and the inducing grooves are configured to direct gases in the volume adjusting horn in a net direction substantially perpendicular to the substrate support.

4. The deposition apparatus of claim 2, wherein the inducing grooves have a shape that is curved clockwise, the mixing region is disc-shaped, and the inducing grooves are connected to the mixing region so as to contact a circumference of the mixing region.

5. The deposition apparatus of claim 2, wherein the inducing grooves have a shape that is curved counterclockwise, the mixing region is disc-shaped, and the inducing grooves are connected to the mixing region so as to contact a circumference of the mixing region.

6. The deposition apparatus of claim 1, further comprising:
a gas outlet for venting gas from the reaction chamber; and
an RF connection port connected to the gas dispersion structure to an RF power supply.

7. The deposition apparatus of claim 6, wherein the gas outlet is disposed at the center of the deposition apparatus, and the process gas supplied to the substrate is subject to collinear exhalation power by the gas outlet.

8. The deposition apparatus of claim 6, wherein an upper portion of the volume adjusting horn has a diameter surrounding the plurality of fine tubules of the helical flow inducing plate, and an inner diameter of the volume adjusting horn widens like a trumpet-shaped structure toward a lower end.

9. The deposition apparatus of claim 1, wherein an upper portion of the volume adjusting horn is connected to the helical flow inducing plate, and an inner diameter of the volume adjusting horn widens like a trumpet-shaped structure toward a lower end.

10. The deposition apparatus of claim 1, wherein the helical flow inducing plate is electrically and mechanically connected to the volume adjusting horn.

11. The deposition apparatus of claim 1, wherein the micro-feeding tube assembly includes an electrically conductive micro-feeding tube sub-assembly connected to the gas inflow tube and an insulating micro-feeding tube sub-assembly connected to the helical flow inducing plate, each of the sub-assemblies having the fine tubules.

12. The deposition apparatus of claim 11, wherein each of a plurality of fine holes of the helical flow inducing plate is aligned with one of the fine tubules of the insulating micro-feeding tube sub-assembly to form a plurality of single conduits.

13. The deposition apparatus of claim 12, wherein the gas inflow tube and the micro-feeding tube assembly are configured to introduce gases substantially perpendicular to the helical flow inducing plate.

14. The deposition apparatus of claim 11, wherein inner diameters of the fine tubules of the electrically conductive micro-feeding tube sub-assembly and the insulating micro-feeding tube sub-assembly are in a range of 0.1 mm to 1.2 mm.

15. The deposition apparatus of claim 14, wherein each of the fine tubules of the electrically conductive micro-feeding tube sub-assembly is aligned with one of the fine tubules of the insulating micro-feeding tube sub-assembly to form a plurality of single conduits.

16. An inlet structure for a vapor deposition tool, the inlet structure comprising:
a plurality of gas inlets connected to separate vapor sources;
a plurality of grooves communicating with and are downstream of the gas inlets for inducing a helical flow;
a mixing region communicating with and a downstream of the grooves for receiving and mixing vapor from the grooves; and
a volume adjusting horn communicating with and a downstream of the mixing region, the volume adjusting horn including a widening downstream portion facing a major surface of a substrate support with no restriction between the widening downstream portion and the substrate support.

17. The inlet structure of claim 16, wherein a downstream end of the widening downstream portion is wider than a substrate for which the substrate support is configured to support.

18. The inlet structure of claim 16, wherein the volume adjusting horn includes a narrow upper portion receiving mixed helical gas flow from the mixing region.

19. The inlet structure of claim 18, wherein the volume adjusting horn further comprises a restriction between the narrow upper portion and the widening downstream portion.

20. A method of feeding a plurality of process gases to a surface of a substrate, the method comprising:
feeding a plurality of process gases through separate inlets;
merging and mixing the process gases in a helical flow; and
passing the mixed process gases through an expanding path in a net perpendicular direction to the surface of the substrate without restriction from the expanding path to the surface.

21. The method of claim 20, wherein the process gases comprise a reactant and an inert gas for an atomic layer deposition.

22. The method of claim 20, wherein the process gases comprises at least two reactants for a chemical vapor deposition.

23. The method of claim 20, further comprising generating a plasma within the expanding path in a wide part of a trumpet-shaped horn facing the surface of the substrate
